(19) United States
(12) Patent Application Publication
(10) Pub. No.: US 2024/0141480 A1
(43) Pub. Date: May 2, 2024

(54) DUAL DEPOSITION CHAMBER APPARATUS FOR PRODUCING SILICON MATERIAL

(71) Applicants: Feng-Yi Precision Technology Co., Ltd., Zhubei City (TW); Blue star advanced materials Co., Ltd., New Taipei City (TW)

(72) Inventors: Chung-Wen LAN, Taipei (TW); Wen-Yi CHIU, Miaoli County (TW); Chao-Kun HSIEH, Miaoli County (TW); Chao-Hsiang HSIEH, Miaoli County (TW)

(21) Appl. No.: 17/979,074

(22) Filed: Nov. 2, 2022

(51) Int. Cl. C23C 16/40; C23C 16/44; C23C 16/455

(52) U.S. Cl. CPC C23C 16/401; C23C 16/4411; C23C 16/45591

(57) ABSTRACT

Provided is a dual deposition chamber apparatus for producing silicon material, the apparatus including a furnace, a cooling jacket, a deposition device, and a vacuum extraction device. The cooling jacket communicates with the furnace, defines a space above the furnace, and includes an opening communicating with the space. The deposition device includes at least one first deposition substrate and at least one second deposition substrate. The at least one first deposition substrate and the at least one second deposition substrate are arranged side by side in the space, and respectively include a first inner wall surface and a second inner wall surface inclined downwards relative to a vertical axis. An uneven area is formed on the first inner wall surface and the second inner wall surface. The vacuum extraction device communicates with the opening of the cooling jacket.

### FIELD OF THE INVENTION

The invention relates to a deposition chamber device, and relates in particular to a dual deposition chamber apparatus for producing a silicon material.

### BACKGROUND OF THE INVENTION

A silicon material is one of the materials widely used in the semiconductor industry. Silicon monoxide is an important raw material for protective insulating layers of semiconductor elements and ceramics, and may also be used in packaging materials for food or medicine. A porous silicon material may be used in various different fields due to unique optoelectronic properties thereof. A conventional deposition chamber apparatus, such as the one provided in Taiwan Patent No. TW 1658002 B, includes a deposition substrate used to deposit silicon monoxide. A conventional deposition chamber apparatus may also be found in Taiwan Patent No. TW 1723730 B, which provides deposition of a magnesium vapor and collection of a remaining porous silicon material. Other deposition chamber apparatuses may also be found in U.S. Pat. Nos. 9,790,095 B2 and 7,431,899 B2, which provide apparatuses for preparing silicon oxide powder and silicon oxide deposits. United States Patent No. US 2007/0259113 A1 provides a method for preparing silicon monoxide. However, the deposition substrate in the deposition chamber apparatus provided in the aforementioned patents has a low deposition rate, resulting in the problem of poor deposition efficiency. Therefore, how to improve the deposition efficiency of a deposition chamber apparatus is an issue to be solved by those skilled in the art.

### SUMMARY OF THE INVENTION

An objective of the invention is to solve the problem in which the production efficiency of a conventional deposition apparatus for a silicon material needs to be improved.

In order to achieve the above-mentioned object, the invention provides a dual deposition chamber apparatus for producing a silicon material, comprising: a furnace; a cooling jacket, arranged above the furnace and communicating with the furnace, the cooling jacket defined with a space above the furnace, and the cooling jacket comprising an opening communicating with the space; a deposition device, comprising at least one first deposition substrate and at least one second deposition substrate, the at least one first deposition substrate and the at least one second deposition substrate arranged side by side in the space of the cooling jacket above the furnace, the at least one first deposition substrate including a first inner wall surface inclined downwards relative to a vertical axis, the at least one second deposition substrate including a second inner wall surface inclined downwards relative to the vertical axis, and each of the first inner wall surface and the second inner wall surface provided an uneven area including a structure concaved or convexed relative to a plane of the first inner wall surface and a plane of the second inner wall surface; and a vacuum extraction device, communicating with the opening of the cooling jacket.

In order to achieve the above-mentioned object, the invention provides a dual deposition chamber apparatus for producing a silicon material, comprising: a furnace; a cooling jacket, arranged above the furnace and communicating with the furnace, wherein the cooling jacket defines a space above the furnace; a deposition device, comprising at least one first deposition substrate and at least one second deposition substrate, the at least one first deposition substrate and the at least one second deposition substrate arranged side by side in the space of the cooling jacket above the furnace, the at least one first deposition substrate including a first inner wall surface inclined downwards relative to a vertical axis, the at least one second deposition substrate including a second inner wall surface inclined downwards relative to the vertical axis, and each of the first inner wall surface and the second inner wall surface provided an uneven area including a structure concaved or convexed relative to a plane of the first inner wall surface and a plane of the second inner wall surface; and an inert gas supply device, communicating with a gas supply inlet of the furnace.

In order to achieve the above-mentioned object, the invention provides a dual deposition chamber apparatus for producing a silicon material, comprising: a furnace; a cooling jacket, arranged above the furnace and communicating with the furnace, the cooling jacket defined with a space above the furnace, and the cooling jacket comprising an opening communicating with the space; a deposition device, comprising at least one first deposition substrate and at least one second deposition substrate, the at least one first deposition substrate and the at least one second deposition substrate arranged side by side in the space of the cooling jacket above the furnace, the at least one first deposition substrate including a first inner wall surface inclined downwards relative to a vertical axis, the at least one second deposition substrate including a second inner wall surface inclined downwards relative to the vertical axis, and each of the first inner wall surface and the second inner wall surface provided an uneven area including a structure concaved or convexed relative to a plane of the first inner wall surface and a plane of the second inner wall surface; a vacuum extraction device, communicating with the opening of the cooling jacket; and an inert gas supply device, communicating with a gas supply inlet of the furnace.

### BRIEF DESCRIPTION OF THE DRAWINGS

FIG. 1 is a schematic diagram of a first embodiment of the invention.

FIG. 2A is a schematic front view of a deposition substrate according to the first embodiment of the invention.

FIG. 2B is a schematic side view of the deposition substrate according to the first embodiment of the invention.

FIG. 3 is an enlarged partial view of the first embodiment of the invention.

FIG. 4 is a schematic cross-sectional diagram taken along A-A of FIG. 3 of the invention.

FIG. 5 is a schematic diagram of a second embodiment of the invention.

FIG. 6 is a schematic diagram of a third embodiment of the invention.

### DETAILED DESCRIPTION OF THE PREFERRED EMBODIMENTS

The terms used herein are merely used for illustrating the specific embodiments and are not intended to limit the invention. As used herein, the singular forms “a”, “an”, and “the” include the plural forms as well, unless the context clearly indicates otherwise.

The directional terms used herein, such as up, down, left, right, front, back, and derivatives or synonyms thereof, refer to the orientations of elements in the accompanying drawings, and are not intended to limit the invention, unless the context clearly indicates otherwise. The detailed description and technical content of the invention are described below with reference to the drawings.

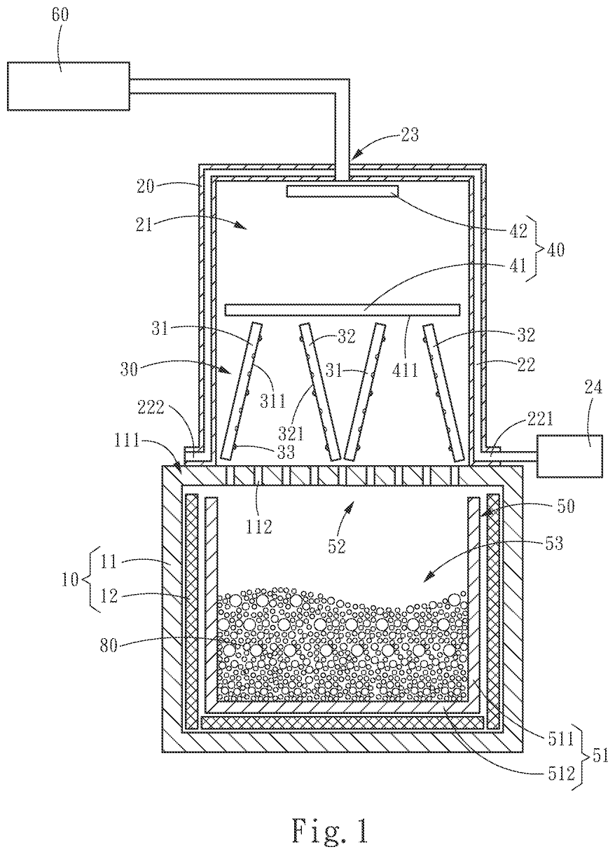

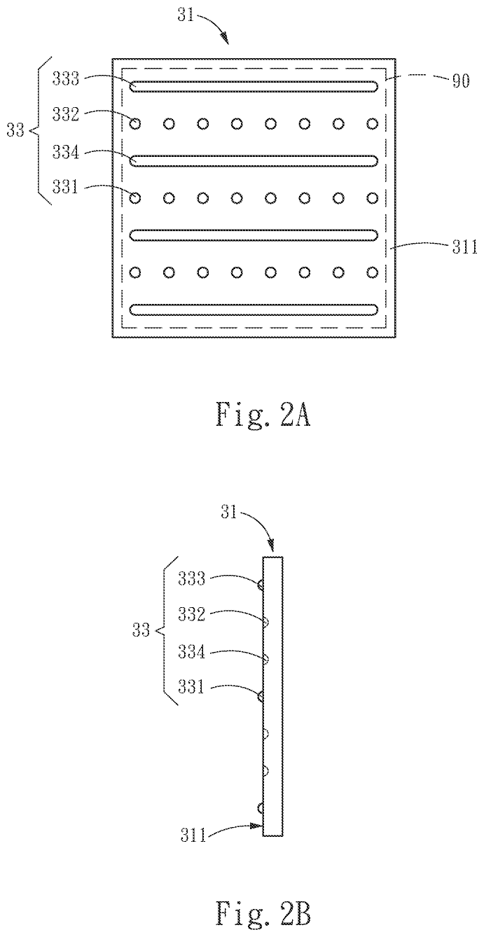

Referring to FIGS. 1, 2A, and 2B, the invention provides a dual deposition chamber apparatus for producing silicon material, including a furnace 10, a cooling jacket 20, a deposition device 30, at least one baffle 40, a crucible 50, and a vacuum extraction device 60.

The furnace 10 includes an insulating base 11 and at least one heater 12. A top portion 111 of the insulating base 11 includes a plurality of through-holes 112 to communicate the furnace 10 with the cooling jacket 20. The at least one heater 12 is arranged on an inner side and a bottom side of the insulating base 11 and surrounds a periphery of the crucible 50. The at least one heater 12 is configured to heat a material 80 to undergo reaction placed in the crucible 50 such that the material 80 forms a reactive vapor. The insulating base 11 is made of a material of carbon fiber, refractory cement, or magnesia brick.

The cooling jacket 20 is arranged above the furnace 10 and communicates therewith, and defines a space 21. The cooling jacket 20 includes a cooling channel 22 and an opening 23. The cooling channel 22 includes an inlet end 221 and an outlet end 222. The inlet end 221 is connected to a cooling device 24 to provide a cooling fluid that flows into the cooling channel 22, and the cooling fluid flows out from the outlet end 222. The cooling fluid includes liquids or gases, for example, the cooling fluid is water, a coolant, or air. The opening 23 is formed in a top portion of the cooling jacket 20 to communicate with the vacuum extraction device 60. By operating the vacuum extraction device 60, the cooling jacket 20 is positioned in a vacuum environment, where pressure of the vacuum environment is less than 1 ton.

The deposition device 30 includes at least one first deposition substrate 31 and at least one second deposition substrate 32. The at least one first deposition substrate 31 and the at least one second deposition substrate 32 are arranged side by side in the space 21 of the cooling jacket 20, and the at least one first deposition substrates 31 and the at least one second deposition substrates 32 face each other. The at least one first deposition substrate 31 includes a first inner wall surface 311. The at least one second deposition substrate 32 includes a second inner wall surface 321. The first inner wall surface 311 and the second inner wall surface 321 are inclined downwards relative to a vertical axis, and are each provided with an uneven area 90. Each of the uneven area 90 includes a structure 33 concaved or convexed relative to a plane of the first inner wall surface 311 and a plane of the second inner wall surface 321. The structure 33 is one or a plurality of protruding points 331, one or a plurality of recessed points 332, one or a plurality of protruding strips 333, one or a plurality of recessed strips 334, or a combination thereof (as shown in FIGS. 2A and 2B, the at least one first deposition substrate 31 is taken as an example in the figures). Further, the distances between every two of the protruding points 331, the recessed points 332, the protruding strips 333, and the recessed strips 334 are the same or different, and the protrusion heights or recess depths of the protruding points 331, the recessed points 332, the protruding strips 333, and the recessed strips 334 are the same or different. The inclination angle of the at least one first deposition substrate 31 and the at least one second deposition substrate 32 relative to the vertical axis is in a range between 10° and 80°. The inclination arrangement of the at least one first deposition substrate 31 and the at least one second deposition substrate 32, and the structure 33 greatly improves the deposition efficiency of the reactive vapor, where the structure 33 facilitates nucleation for the reactive vapor. In this embodiment, two first deposition substrates 31 and two second deposition substrates 32 are provided, and are sequentially arranged in the space 21 of the cooling jacket 20 in the sequence of the first deposition substrate 31, the second deposition substrate 32, the first deposition substrate 31, and the second deposition substrate 32 from left to right, where the first inner wall surfaces 311 of the two first deposition substrates 31 and the second inner wall surfaces 321 of the two second deposition substrates 32 are arranged face to face but not in parallel, the two first deposition substrate 31 are inclined by an angle clockwise relative to the vertical axis, and the two second deposition substrate 32 are inclined by the angle counterclockwise relative to the vertical axis. In one embodiment, a plurality of first deposition substrate 31 and a plurality of second deposition substrate 32 are arranged in the space 21 of the cooling jacket 20 in vertically arranged layers. In detail, the space 21 is divided into an upper layer and a lower layer, and both the upper layer and the lower layer are provided with the plurality of first deposition substrate 31 and the plurality of second deposition substrate 32.

The at least one baffle 40 is arranged in the space 21 and positioned between the opening 23 of the cooling jacket 20 and the deposition device 30. In one embodiment, the at least one baffle 40 includes a first baffle 41 and a second baffle 42. The first baffle 41 is arranged above the deposition device 30, and blocks the reactive vapor from flowing upwards so as to prolong the deposition time of the reactive vapor in the deposition device 30, thereby improving deposition efficiency, and the reactive vapor may also be deposited on the first baffle 41. The second baffle 42 is arranged on a side of the cooling jacket 20 close to the opening 23 to block the reactive vapor from being extracted out of the cooling jacket 20 to enter the vacuum extraction device 60. In an embodiment, a lower surface 411 of the first baffle 41 is provided with the structure 33 (not shown).

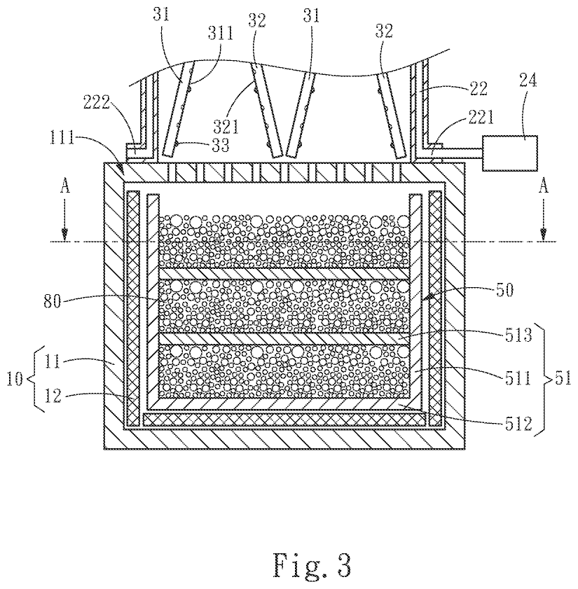

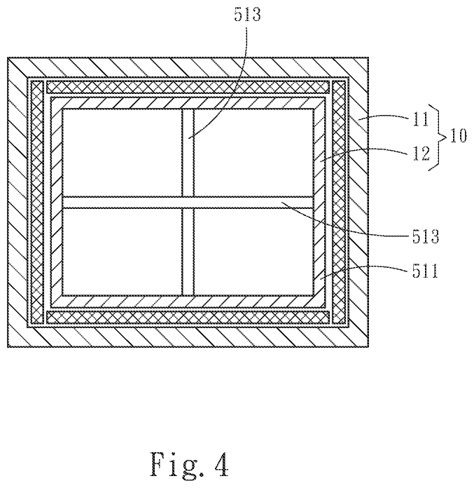

The crucible 50 is arranged in the furnace 10 and includes a body 51 and an upper opening 52. The body 51 includes a surrounding wall 511 and a bottom wall 512. The surrounding wall 511 and the bottom wall 512 define an accommodation space 53. The accommodation space 53 is configured to accommodate the material 80. Further referring to FIGS. 3 and 4, in an embodiment, the body 51 further includes at least one auxiliary heating rib 513. The at least one auxiliary heating rib 513 is connected to the surrounding wall 511 and penetrates the accommodation space 53, and provides a uniform heating effect for the material 80 placed in the crucible 50. In one embodiment, there are a plurality of auxiliary heating ribs 513 arranged in the accommodation space 53 in a crisscross manner. The number and arrangement of the auxiliary heating ribs 513 in another embodiments are not limited thereto. The crucible 50 is made of ceramic, graphite, platinum, nickel, or chromium.

In a first embodiment, the dual deposition chamber apparatus is used to form a silicon monoxide deposit by deposition. First, silicon powder is placed in the crucible 50. The crucible 50 is heated through the at least one heater 12 to a first temperature and the temperature is maintained for a first heating time, such that a silicon dioxide layer is formed on surface of the silicon powder, and a silicon dioxide shell/silicon core composite powder is formed. The first temperature is in a range between 600° C. and 900° C., and the first heating time ranges from 12 hours to 36 hours.

Then, the vacuum extraction device 60 operates to generate the vacuum environment in the cooling jacket 20 and the furnace 10, and the at least one heater 12 continuously heats the crucible 50 to a second temperature, such that a silicon dioxide shell and a silicon core of the silicon dioxide shell/silicon core composite powder react to form silicon monoxide, and the silicon monoxide is sublimated into a silicon monoxide vapor. The second temperature is in a range between 1,200° C. and 1,450° C.

Finally, the silicon monoxide vapor drifts to the space 21 of the cooling jacket 20 via the plurality of through-holes 112 of the furnace 10, and the silicon monoxide vapor is cooled and deposited on the at least one first deposition substrate 31 and the at least one second deposition substrate 32 of the deposition device 30 to form the silicon monoxide deposit.

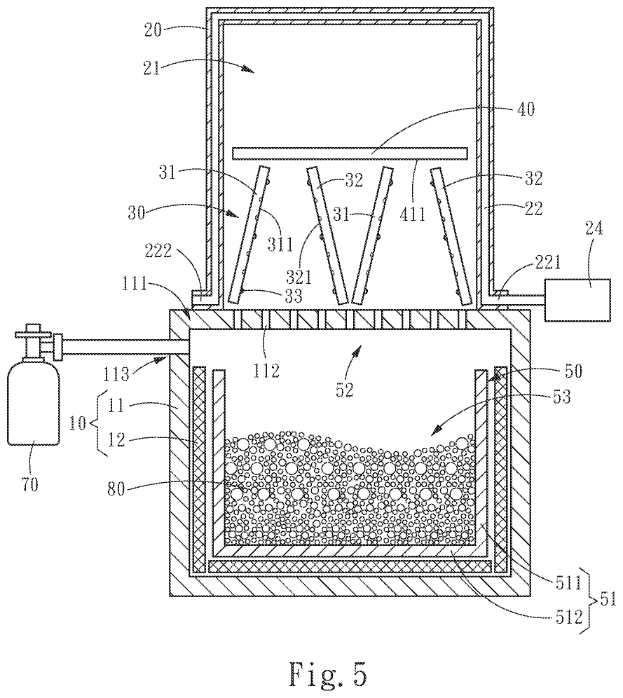

Referring to FIG. 5, which is a schematic diagram of a second embodiment of the invention, in this embodiment, the structure of a dual deposition chamber apparatus for producing a silicon material is substantially the same as the structure of the first embodiment, and a difference is that in this embodiment, an inert gas supply device 70 is substituted for the vacuum extraction device 60 of the first embodiment. The inert gas supply device 70 is arranged at a gas supply inlet 113 of the insulating base 11 of the furnace 10 and communicates therewith, so as to provide an inert gas that enters the accommodation space 53. The inert gas is argon or nitrogen. In this embodiment, the at least one baffle 40 is arranged in the space 21 and positioned above the deposition device 30.

In the second embodiment, the dual deposition chamber apparatus is used to form a silicon monoxide deposit by deposition. First, silicon powder is placed in the crucible 50. The crucible 50 is heated through the at least one heater 12 to the first temperature and the temperature is maintained for the first heating time, such that the silicon dioxide layer is formed on surface of the silicon powder, and a silicon dioxide shell/silicon core composite powder is formed.

Then, the inert gas supply device 70 operates to generate an inert atmosphere in the cooling jacket 20 and the furnace 10, and the at least one heater 12 continuously heats the crucible 50 to the second temperature, such that the silicon dioxide shell and the silicon core of the silicon dioxide shell/silicon core composite powder react to form the silicon monoxide, and the silicon monoxide is sublimated into the silicon monoxide vapor.

Finally, the silicon monoxide vapor drifts to the space 21 of the cooling jacket 20 via the plurality of through-holes 112 of the furnace 10, and the silicon monoxide vapor is cooled and deposited on the at least one first deposition substrate 31 and the at least one second deposition substrate 32 of the deposition device 30 to form the silicon monoxide deposit.

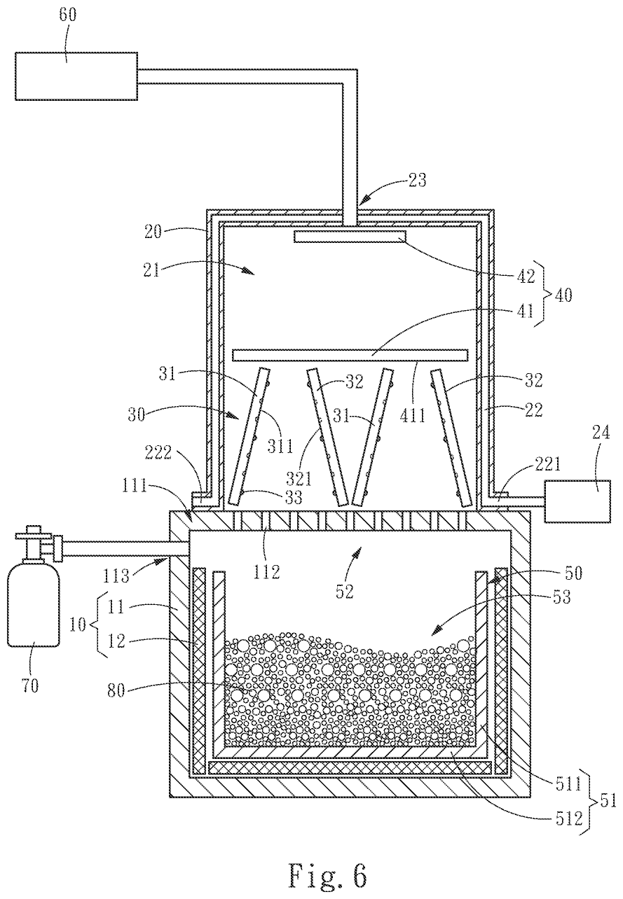

Referring to FIG. 6, which is a schematic diagram of a third embodiment of the invention, in this embodiment, the structure of a dual deposition chamber apparatus for producing a silicon material is substantially the same as the structures of the first and second embodiments, and a difference is that this embodiment includes both the vacuum extraction device 60 and the inert gas supply device 70. The vacuum extraction device 60 communicates with the opening 23. The inert gas supply device 70 communicates with the gas supply inlet 113.

In the third embodiment, the dual deposition chamber apparatus is to form a silicon monoxide deposit by deposition. First, silicon powder is placed in the crucible 50. The crucible 50 is heated through the at least one heater 12 to the first temperature and the temperature is maintained for the first heating time, such that the silicon dioxide layer is formed on the surface of the silicon powder, and a silicon dioxide shell/silicon core composite powder is formed.

Then, the vacuum extraction device 60 operates to generate the vacuum environment in the cooling jacket 20 and the furnace 10, the inert gas supply device 70 introduces inert gas such that an inert atmosphere is provided in the cooling jacket 20 and the furnace 10, and the at least one heater 12 continuously heats the crucible 50 to the second temperature, such that the silicon dioxide shell and the silicon core of the silicon dioxide shell/silicon core composite powder react to form the silicon monoxide, and the silicon monoxide is sublimated into the silicon monoxide vapor.

Finally, the silicon monoxide vapor drifts to the space 21 of the cooling jacket 20 via the plurality of through-holes 112 of the furnace 10, and the silicon monoxide vapor is cooled and deposited on the at least one first deposition substrate 31 and the at least one second deposition substrate 32 of the deposition device 30 to form the silicon monoxide deposit.

In conclusion, in the invention, the first inner wall surface of the first deposition substrate and the second inner wall surface of the second deposition substrate are inclined downwards relative to the vertical axis, and the first inner wall surface and the second inner wall surface are provided with the uneven area, so that the reactive vapor generated after heating of the material may be effectively received, thereby greatly improving deposition efficiency. In addition, the uneven area facilitates nucleation of the reactive vapor.

What is claimed is:

1. A dual deposition chamber apparatus for producing a silicon material, comprising:
a furnace;
a cooling jacket, arranged above the furnace and communicating with the furnace, the cooling jacket defined with a space above the furnace, and the cooling jacket comprising an opening communicating with the space;
a deposition device, comprising at least one first deposition substrate and at least one second deposition substrate, the at least one first deposition substrate and the at least one second deposition substrate arranged side by side in the space of the cooling jacket above the furnace, the at least one first deposition substrate including a first inner wall surface inclined downwards relative to a vertical axis, the at least one second deposition substrate including a second inner wall surface inclined downwards relative to the vertical axis, and each of the first inner wall surface and the second inner wall surface provided with an uneven area including a structure concaved or convexed relative to a plane of the first inner wall surface and a plane of the second inner wall surface; and
a vacuum extraction device, communicating with the opening of the cooling jacket.

2. The apparatus according to claim 1, wherein the apparatus comprises at least one baffle, and the at least one baffle arranged in the space and positioned between the opening of the cooling jacket and the deposition device.

3. The apparatus according to claim 1, wherein the structure is one or a plurality of protruding points, one or a plurality of recessed points, one or a plurality of protruding strips, one or a plurality of recessed strips, or a combination thereof.

4. The apparatus according to claim 1, wherein the apparatus comprises a crucible arranged in the furnace, the crucible comprising a body and an upper opening, wherein the body is defined with an accommodation space and comprises a surrounding wall, a bottom wall, and at least one auxiliary heating rib connected to the surrounding wall and penetrating the accommodation space.

5. A dual deposition chamber apparatus for producing a silicon material, comprising:
a furnace;
a cooling jacket, arranged above the furnace and communicating with the furnace, wherein the cooling jacket defines a space above the furnace;
a deposition device, comprising at least one first deposition substrate and at least one second deposition substrate, the at least one first deposition substrate and the at least one second deposition substrate arranged side by side in the space of the cooling jacket above the furnace, the at least one first deposition substrate including a first inner wall surface inclined downwards relative to a vertical axis, the at least one second deposition substrate including a second inner wall surface inclined downwards relative to the vertical axis, and each of the first inner wall surface and the second inner wall surface provided with an uneven area including a structure concaved or convexed relative to a plane of the first inner wall surface and a plane of the second inner wall surface; and
an inert gas supply device, communicating with a gas supply inlet of the furnace.

6. The apparatus according to claim 5, wherein the apparatus comprises at least one baffle, and the at least one baffle arranged in the space and positioned above the deposition device.

7. The apparatus according to claim 5, wherein the structure is one or a plurality of protruding points, one or a plurality of recessed points, one or a plurality of protruding strips, one or a plurality of recessed strips, or a combination thereof.

8. The apparatus according to claim 5, wherein the apparatus comprises a crucible arranged in the furnace, the crucible comprising a body and an upper opening, wherein the body defines an accommodation space and comprises a surrounding wall, a bottom wall, and at least one auxiliary heating rib connected to the surrounding wall and penetrating the accommodation space.

9. A dual deposition chamber apparatus for producing a silicon material, comprising:
a furnace;
a cooling jacket, arranged above the furnace and communicating with the furnace, the cooling jacket defined with a space above the furnace, and the cooling jacket comprising an opening communicating with the space;
a deposition device, comprising at least one first deposition substrate and at least one second deposition substrate, the at least one first deposition substrate and the at least one second deposition substrate arranged side by side in the space of the cooling jacket above the furnace, the at least one first deposition substrate including a first inner wall surface inclined downwards relative to a vertical axis, the at least one second deposition substrate including a second inner wall surface inclined downwards relative to the vertical axis, and each of the first inner wall surface and the second inner wall surface provided with an uneven area including a structure concaved or convexed relative to a plane of the first inner wall surface and a plane of the second inner wall surface;
a vacuum extraction device, communicating with the opening of the cooling jacket; and
an inert gas supply device, communicating with a gas supply inlet of the furnace.

10. The apparatus according to claim 9, wherein the apparatus comprises at least one baffle, and the at least one baffle arranged in the space and positioned between the opening of the cooling jacket and the deposition device.

11. The apparatus according to claim 9, wherein the structure is one or a plurality of protruding points, one or a plurality of recessed points, one or a plurality of protruding strips, one or a plurality of recessed strips, or a combination thereof.

12. The apparatus according to claim 9, wherein the apparatus comprises a crucible arranged in the furnace, the crucible comprising a body and an upper opening, wherein the body defines an accommodation space and comprises a surrounding wall, a bottom wall, and at least one auxiliary heating rib connected to the surrounding wall and penetrating the accommodation space.
